(19) United States
(12) Patent Application Publication
(10) Pub. No.: US 2026/0100698 A1
(43) Pub. Date: Apr. 9, 2026

(54) DYNAMIC HIGH-SPEED FLIP FLOP

(71) Applicant: QUALCOMM Incorporated, San Diego, CA (US)

(72) Inventors: Peter Normand LABRECQUE, Austin, TX (US); Anik SRIVASTAVA, Pflugerville, TX (US); Sumeer GOEL, Austin, TX (US)

(21) Appl. No.: 18/908,295

(22) Filed: Oct. 7, 2024

(51) Int. Cl. H03K 3/3562; H03K 3/012

(52) U.S. Cl. CPC H03K 3/35625; H03K 3/012

(57) ABSTRACT

Aspects of the disclosure are directed to a dynamic master slave flip flop circuit. In accordance with one aspect, the disclosure includes a master latch section configured to receive an input signal asserted at a HIGH state of the input signal; a clock circuit coupled to the master latch section, the clock circuit configured to execute a positive clock transition of a clock signal; and a slave latch section coupled to the master latch section and the clock circuit, the slave latch section configured to transition a state (Q) signal from a LOW state to a HIGH state of the state (Q) signal subsequent to the positive clock transition.

### TECHNICAL FIELD

This disclosure relates generally to the field of digital electronics circuits, and, in particular, to a high-speed low glitch flip flop digital electronics circuit.

### BACKGROUND

Digital electronics circuits may include both combinational and sequential circuits. A fundamental circuit element for sequential circuits is a flip flop circuit, which is a bistable circuit which may retain state information. The flip flop circuit may conform to several performance requirements including fast access time and low glitch susceptibility which may be conflicting requirements. Hence, there is a need for a flip flop circuit design which is compatible with both fast switching speed and a low probability of an output glitch.

### SUMMARY

The following presents a simplified summary of one or more aspects of the present disclosure, in order to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present some concepts of one or more aspects of the disclosure in a simplified form as a prelude to the more detailed description that is presented later.

In one aspect, the disclosure provides a dynamic master slave flip flop circuit. Accordingly, the present disclosure discloses an apparatus including: a master latch section configured to receive an input signal asserted at a HIGH state of the input signal; a clock circuit coupled to the master latch section, the clock circuit configured to execute a positive clock transition of a clock signal; and a slave latch section coupled to the master latch section and the clock circuit, the slave latch section configured to transition a state (Q) signal from a LOW state to a HIGH state of the state (Q) signal subsequent to the positive clock transition.

In one example, the apparatus further includes a first slave latch transistor configured to implement a glitch mitigation in the slave latch section. In one example, the first slave latch transistor is housed within the slave latch section. In one example, the first slave latch transistor is a metal oxide semiconductor (MOS) transistor. In one example, the metal oxide semiconductor (MOS) transistor is an n-channel MOS (NMOS) transistor. In one example, the apparatus further includes a second slave latch transistor housed within the slave latch section, the second slave latch transistor configured to gate the positive clock transition.

Another aspect of the disclosure provides an apparatus including: means for receiving an input signal asserted at a HIGH state of the input signal at a master latch section, and at a slave latch section with a glitch mitigation; means for executing a positive clock transition throughout the master latch section and the slave latch section; and means for transitioning a state (Q) signal from a LOW state to a HIGH state of the state (Q) signal subsequent to the positive clock transition.

In one example, the apparatus further includes means for transitioning a complementary state (QB) signal from a first state to a second state subsequent to the positive clock transition. In one example, the apparatus further includes means for receiving the input signal deasserted at a LOW state. In one example, the apparatus further includes means for inputting the input signal.

Another aspect of the disclosure provides a method including: receiving an input signal asserted at a HIGH state of the input signal at a master latch section, and at a slave latch section with a glitch mitigation; executing a positive clock transition throughout the master latch section and the slave latch section; and transitioning a state (Q) signal from a LOW state to a HIGH state of the state (Q) signal subsequent to the positive clock transition.

In one example, the positive clock transition is gated in a keeper circuit. In one example, the positive clock transition is a rising edge of a periodic clock signal. In one example, the periodic clock signal is established using a frequency reference. In one example, the method further includes transitioning a complementary state (QB) signal from a first state to a second state subsequent to the positive clock transition. In one example, the complementary state (QB) signal tracks a complement of the input signal with a first delay.

In one example, the state (Q) signal tracks the input signal with a second delay. In one example, the method further includes receiving the input signal deasserted at a LOW state at the master latch section, and at the slave latch section with the glitch mitigation. In one example, the method further includes inputting the input signal to the master latch section and to the slave latch section. In one example, the input signal is received prior to a setup time margin relative to the positive clock transition.

These and other aspects of the present disclosure will become more fully understood upon a review of the detailed description, which follows. Other aspects, features, and implementations of the present disclosure will become apparent to those of ordinary skill in the art, upon reviewing the following description of specific, exemplary implementations of the present invention in conjunction with the accompanying figures. While features of the present invention may be discussed relative to certain implementations and figures below, all implementations of the present invention can include one or more of the advantageous features discussed herein. In other words, while one or more implementations may be discussed as having certain advantageous features, one or more of such features may also be used in accordance with the various implementations of the invention discussed herein. In similar fashion, while exemplary implementations may be discussed below as device, system, or method implementations it should be understood that such exemplary implementations can be implemented in various devices, systems, and methods.

### BRIEF DESCRIPTION OF THE DRAWINGS

FIG. 1 illustrates a first example master slave flip flop circuit.

FIG. 2 illustrates a second example master slave flip flop circuit.

FIG. 3 illustrates a third example master slave flip flop circuit.

FIG. 4 illustrates an example timing diagram for an example master slave flip flop circuit.

FIG. 5 illustrates a fourth example master slave flip flop circuit.

FIG. 6 illustrates a fifth example master slave flip flop circuit.

FIG. 7 illustrates an example flow diagram 700 for implementing a dynamic master slave flip flop circuit.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

While for purposes of simplicity of explanation, the methodologies are shown and described as a series of acts, it is to be understood and appreciated that the methodologies are not limited by the order of acts, as some acts may, in accordance with one or more aspects, occur in different orders and/or concurrently with other acts from that shown and described herein. For example, those skilled in the art will understand and appreciate that a methodology could alternatively be represented as a series of interrelated states or events, such as in a state diagram. Moreover, not all illustrated acts may be required to implement a methodology in accordance with one or more aspects.

In one example, a custom memory for a processing engine may require a very short access time to achieve fast processing speeds. One key element use to enable such speed is a high-speed flip flop, a bistable circuit which retains state information. In one example, a high-speed flip flop may be implemented using a standard master slave flip flop circuit with high insertion delay and which may require adherence to a significant internal master to slave hold timing margin.

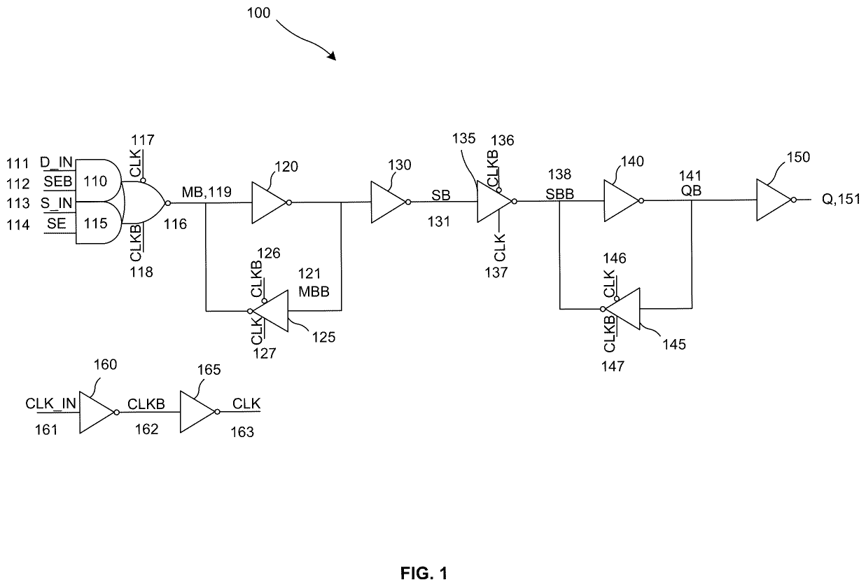

FIG. 1 illustrates a first example master slave flip flop circuit 100. In one example, the first example master slave flip flop circuit 100 includes an input section with first AND gate 110 and a second AND gate 115 coupled to a NOR gate 116. In one example, the first AND gate 110 has a data input (D_IN) 111 and a scan enable bar (SEB) input 112. In one example, the second AND gate 115 has a scan input (S_IN) 113 and a scan enable (SE) input 114. In one example, the SEB input 112 is a logical complement of the SE input 114 (i.e., the SEB input 112 and the SE input 114 have opposite logical states). In one example, if the SEB input 112 is asserted HIGH, a data mode is enabled and the data input (D_IN) 111 is coupled to a first AND output of the second AND gate 115. In one example, if the SE input 114 is asserted HIGH, a scan mode is enabled and the scan input (S_IN) 113 is coupled to a second AND output of the second AND gate 115.

In one example, the first NOR gate 116 accepts the first AND output and the second AND output with a clock signal (CLK) 117 and a clock bar signal (CLKB) 118 to produce a MB signal 119. In one example, the MB signal 119 is asserted HIGH (i.e., ONE) only if both the first AND output and the second AND output are asserted LOW (i.e., ZERO). Otherwise, the MB signal 119 is asserted LOW.

In one example, the MB signal 119 is sent to a first inverter loop with a first inverter 120 and a second inverter 125 configured in a feedback loop. In one example, the second inverter 125 receives a clock signal (CLK) 127 and a clock bar signal (CLKB) 126. In one example, the first inverter loop produces a MBB signal 121 as its output. In one example, the MBB signal 121 is a logical complement of the MB signal 119.

In one example, the MBB signal 121 is sent to a third inverter 130 to form a SB signal 131. In one example, the SB signal 131 is sent to a fourth inverter 135 to produce a SBB signal 138 as its output. In one example, the fourth inverter 135 receives a clock signal (CLK) 137 and a clock bar signal (CLKB) 136. In one example, the SB signal 131 is generated by an inverter stage. In one example, the SBB signal 138 is generated by a slave latch in a master-slave flip flop circuit.

In one example, the SBB signal 138 is sent to a second inverter loop with a fifth inverter 140 and a sixth inverter 145 configured in a feedback loop. In one example, the sixth inverter 145 receives a clock signal (CLK) 146 and a clock bar signal (CLKB) 147. In one example, the second inverter loop produces a QB signal 141 as its output. In one example, the QB signal 141 is send to a seventh inverter 150 to produce a Q signal 151. In one example, the QB signal 141 is a logical complement of the Q signal 151.

In one example, a clock input signal (CLK_IN) 161 is sent to an eighth inverter 160 to produce a clock bar signal (CLKB) 162. In one example, the clock bar signal 162 is sent to a ninth inverter 165 to produce a clock signal (CLK) 163.

In one example, the first example master slave flip flop circuit 100 is a standard master slave flip flop circuit and requires an extra local clock driver circuit. In one example, a stage depth from the CLK signal 163 to the Q signal 151 may be either 3 or 4 stages. In one example, a master to slave hold margin may require a buffer circuit between the MB signal 119 and the SB signal 131. In one example, the example master slave flip flop circuit 100 may operate slower than required by an application and may need extra timing margin for proper operation. In one example, a stage is a unit of circuit delay. In one example, a stage is a circuit element with an input and an output. In one example, each stage contributes a delay between the input and the output.

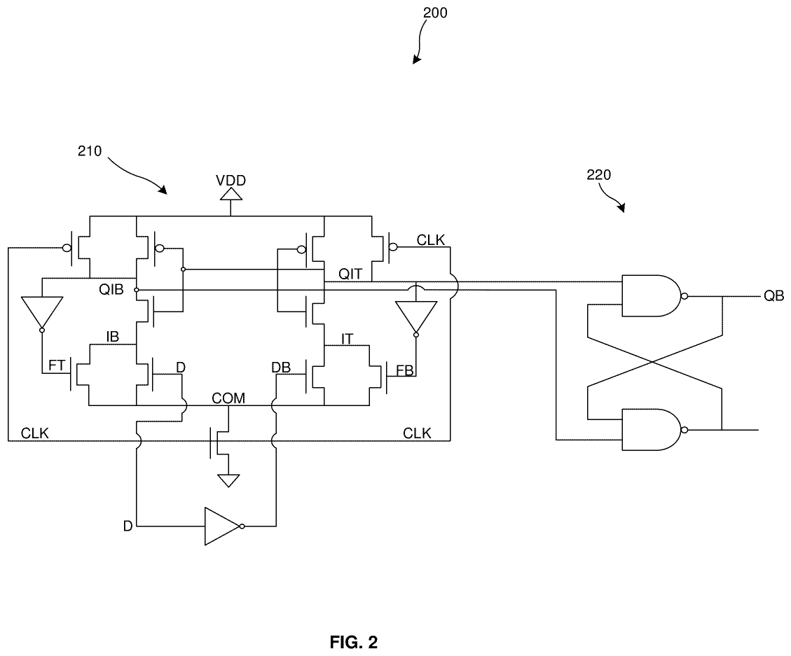

FIG. 2 illustrates a second example master slave flip flop circuit 200. In one example, the second example master slave flip flop circuit 200 includes a dynamic master latch section 210 and a static slave latch section 220. In one example, the static slave latch section 220 utilizes a set-reset (SR) latch. In one example, the second example master slave flip flop circuit 200 retains a bilevel state of a data (D) input signal in an output state (Q) signal. In one example, the second example master slave flip flop circuit 200 has a shorter circuit delay than the first example master slave flip flop circuit 100. In one example, the second example master slave flip flop circuit 200 may utilize an extra driver circuit for large loads.

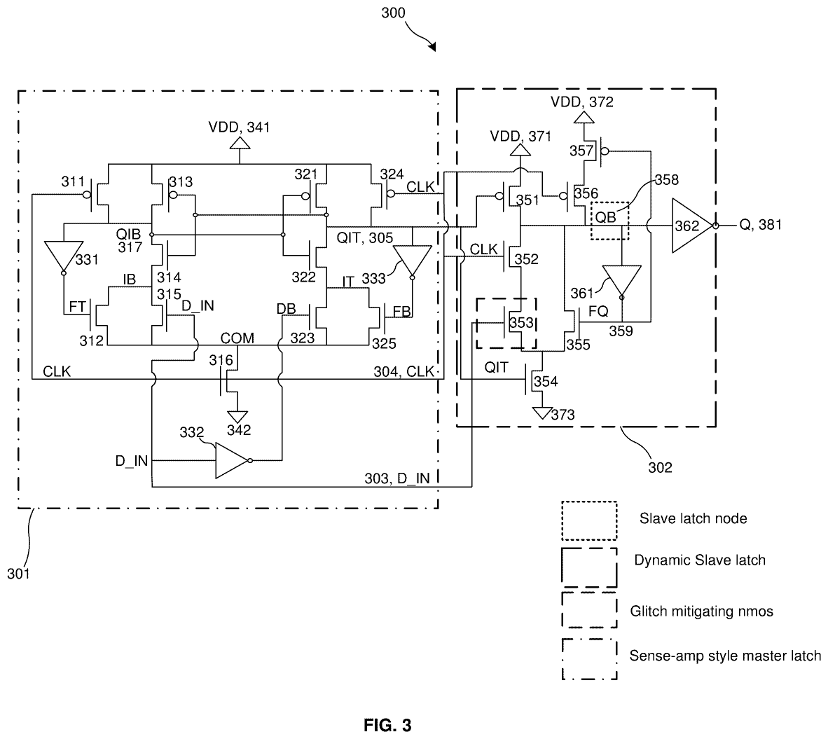

FIG. 3 illustrates a third example master slave flip flop circuit 300. In one example, the third example master slave flip flop circuit 300 includes a master latch section 301 and a slave latch section 302. For example, the third example master slave flip flop circuit 300 is a high-speed dynamic flip flop circuit.

In one example, a data input (D_IN) signal 303 serves as an input to the master latch section 301. The master latch section 301 may include a first master latch transistor 311, a second master latch transistor 312, a third master latch transistor 313, a fourth master latch transistor 314, a fifth master latch transistor 315, a sixth master latch transistor 316, a seventh master latch transistor 321, an eighth master latch transistor 322, a ninth master latch transistor 323, a tenth master latch transistor 324 and an eleventh master latch transistor 325. In one example, the master latch section 301 also includes a first inverter 331, a second inverter 332 and a third inverter 333. In one example, the master latch section 301 also includes a drain supply voltage VDD 341 and a ground terminal 342.

In one example, the master latch section 301 generates a QIB signal 317 and a QIT signal 305. For example, the QIT signal 305 is an intermediate state signal sent to the slave latch section 302 as a precharged signal. In one example, the master latch section 301 operates with a clock signal 304 which is also sent to the slave latch section 302 for synchronous operation.

In one example, the data input (D_IN) signal 303 serves as an input to the slave latch section 302. The slave latch section 302 may include a first slave latch transistor 351 coupled to a second slave latch transistor 352 coupled to a third slave latch transistor 353 coupled to a fourth slave latch transistor 354. In one example, the first slave latch transistor 351 is sourced by a drain supply voltage VDD 371 at its drain terminal. In one example, the fourth slave latch transistor 354 is sunk by a ground terminal 373 at its source terminal. In one example, the first slave latch transistor 351, second slave latch transistor 352, third slave latch transistor 353 and the fourth slave latch transistor 354 are each metal oxide semiconductor (MOS) transistors. In one example, each MOS transistor has a gate terminal, a drain terminal and a source terminal. In one example, each MOS transistor is an n-channel MOS (NMOS) transistor.

In one example, the first slave latch transistor 351 receives a complement of a QIT signal 305 from the master latch section 301 into its gate terminal. In one example, the second slave latch transistor 352 receives the clock signal 304 from the master latch section 301 into its gate terminal. In one example, the QIT signal 305 is precharged prior to a rising edge transition of the clock signal 304.

In one example, the data input (D_IN) signal 303 is sent to the third slave latch transistor 353 at its gate terminal. For example, when the data input signal 303 is asserted HIGH, the third slave latch transistor 353 allows current flow from its drain terminal to its source terminal. For example, when the data input signal 303 is asserted LOW, the third slave latch transistor 353 blocks current flow from its drain terminal to its source terminal. In one example, the third slave latch transistor 353 operates as a glitch-mitigating transistor. For example, the third slave latch transistor 353 prevents an output signal glitch from occurring by pulling down a voltage in an output portion of the slave latch section 302.

In one example, the fourth slave latch transistor 354 receives the QIT signal 305 from the master latch section 301 into its gate terminal. In one example, the first slave latch transistor 351 and the fourth slave latch transistor 354 operate in a complementary manner according to the state of the QIT signal 305. For example, if the QIT signal 305 is asserted HIGH, the first slave latch transistor 351 blocks current flow between its drain terminal and its source terminal and the fourth slave latch transistor 354 allows current flow between its drain terminal and its source terminal. For example, if the QIT signal 305 is asserted LOW, the first slave latch transistor 351 allows current flow between its drain terminal and its source terminal and the fourth slave latch transistor 354 blocks current flow between its drain terminal and its source terminal.

The slave latch section 302 may include a fifth slave latch transistor 357 coupled to a sixth slave latch transistor 356 coupled to a seventh slave latch transistor 355 coupled to the fourth slave latch transistor 354. In one example, the fifth slave latch transistor 357 is sourced by the drain supply voltage VDD 372 (same as drain supply voltage VDD 371) at its drain terminal. In one example, the fourth slave latch transistor 354 is sunk by a ground 373 at its source terminal. In one example, the fifth slave latch transistor 357, the sixth slave latch transistor 356, the seventh slave latch transistor 355 and the fourth slave latch transistor 354 are each metal oxide semiconductor (MOS) transistors. In one example, each MOS transistor has a gate terminal, a drain terminal and a source terminal. In one example, each MOS transistor is an n-channel MOS (NMOS) transistor.

In one example, a QB signal 358 is an output from the first slave latch transistor 351 and the sixth slave latch transistor 356. In one example, the QB signal 358 is sent to a first slave inverter 361 to produce a FQ signal 359 as a gate input to the seventh slave latch transistor 355 and a complementary gate input to the fifth slave latch transistor 357. In one example, the FQ signal 359 is a logical complement of the QB signal 358. In one example, the FQ signal 359 is a feedback Q signal with the same polarity as a Q signal 381.

In one example, the QB signal 358 is also sent to a second slave inverter 362 to produce a Q signal 381. In one example, the Q signal 381 is a logical complement of the QB signal 358. In one example, the Q signal 381 represents the state output of the third example master slave flip flop circuit 300.

In one example, the data input (D_IN) signal 303 is an input to the master latch section 301 and the slave latch section 302. For example, the data input signal 303 is set up at the master latch section 301. For example, the data input signal 303 is also gated at the slave latch section 302 to prevent a signal glitch during a negative transition (i.e., HIGH state to LOW state) of the Q signal 381. In one example, since the clock signal 304 is gated in a keeper circuit, no internal master slave hold is required. In one example, the keeper circuit maintains the state of a dynamic circuit.

In one example, once the clock signal 304 rises to a HIGH state, the data input signal 303 forces the QIT signal 305 to fall to a LOW state. For example, the QIT signal 305 is precharged prior to the transition of the clock signal 304, since the slave latch section 302 is dynamic.

In one example, when the data input signal 303 is at a HIGH state, a positive transition (i.e., LOW state to HIGH state) of the clock signal 304 causes the QB signal 358 to fall to a LOW state after only one stage (i.e., one unit of circuit delay), in the slave latch section 302.

In one example, when the data input signal 303 is at a LOW state, a positive transition of the clock signal 304 causes the QIT signal 305 to fall to a LOW state in the master latch section 301 and causes the QB signal 358 to rise to a HIGH state.

In one example, a setup time for the data input signal 303 is established at the fifth master latch transistor 315 and the ninth master latch transistor 323. In one example, a hold time for the data input signal 303 is established at the second master latch transistor 312 and the eleventh master latch transistor 325 in the master latch section 301 and in the fourth slave latch transistor 354 in the slave latch section 302.

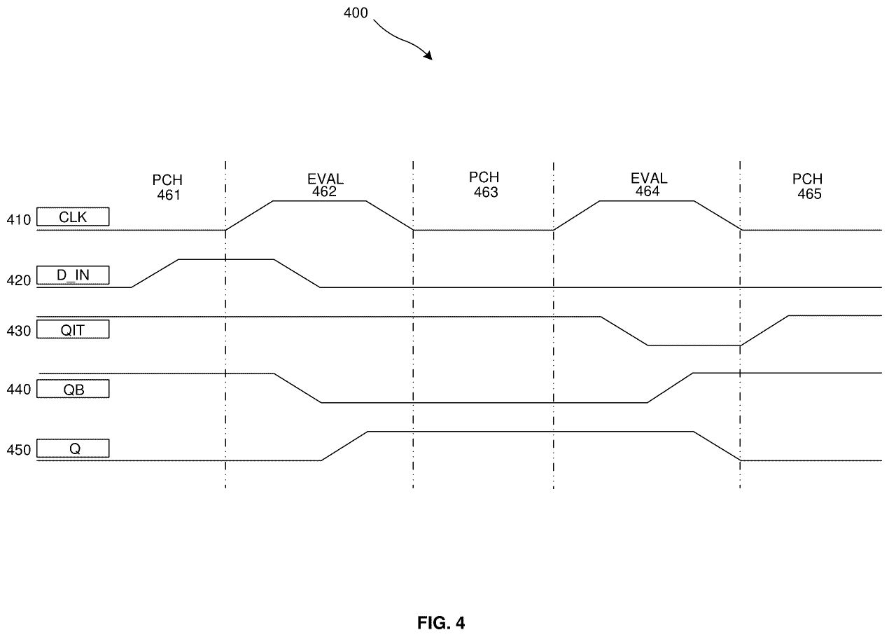

FIG. 4 illustrates an example timing diagram 400 for an example master slave flip flop circuit. In one example, the timing diagram 400 includes a clock (CLK) signal trace 410, a data input (D_IN) signal trace 420, a QIT signal trace 430, a QB signal trace 440 and a Q signal trace 450. In one example, the timing diagram 400 may be partitioned into a plurality of time phases including a first precharge (PCH) phase 461, a first evaluate (EVAL) data phase 462, a second precharge phase 463, a second evaluate data phase 464 and a third precharge phase 465, etc.

In one example, during the first PCH phase 461, the clock signal trace 410 is at a LOW state while the data input signal trace 420 transitions to a HIGH state. In one example, the QIT signal trace 430 remains at a HIGH state, the QB signal trace 440 remains at a HIGH state and the Q signal trace remains at a LOW state.

In one example, during the first EVAL phase 462, the clock signal trace 410 transitions to a HIGH state while the data input signal trace 420 transitions to a LOW state. In one example, the QIT signal trace 430 remains at the HIGH state. In one example, the QB signal trace 440 transitions to a LOW state and the Q signal trace 450 transitions to a HIGH state. In one example, the Q signal trace 450 latches the logical value of the data input signal trace 420 at the time of the clock signal trace 410 transition to the HIGH state.

In one example, during the second PCH phase 463, the clock signal trace 410 transitions to a LOW state while the data input signal trace 420 remains at the LOW state. In one example, the QIT signal trace 430 remains at the HIGH state while the QB signal trace 440 remains in the LOW state. In one example, the Q signal trace 450 remains at the HIGH state.

In one example, during the second EVAL phase 464, the clock signal trace 410 transitions to a HIGH state while the data input signal trace 420 remains at the LOW state. In one example, the QIT signal trace 430 transitions to a LOW state, the QB signal trace 440 transitions to a HIGH state and the Q signal trace 450 transitions to a LOW state. For example, the Q signal trace 450 transition during the second EVAL phase 464 tracks the data input signal trace 420 transitions during the first EVAL phase 462.

In one example, during the third PCH phase 465, the clock signal trace 410 transitions to a LOW state while the data input signal state 420 remains at the LOW state. In one example, the QIT signal trace 430 transitions to a HIGH state, the QB signal trace 440 remains at the HIGH state and the Q signal trace 450 remains at the LOW state.

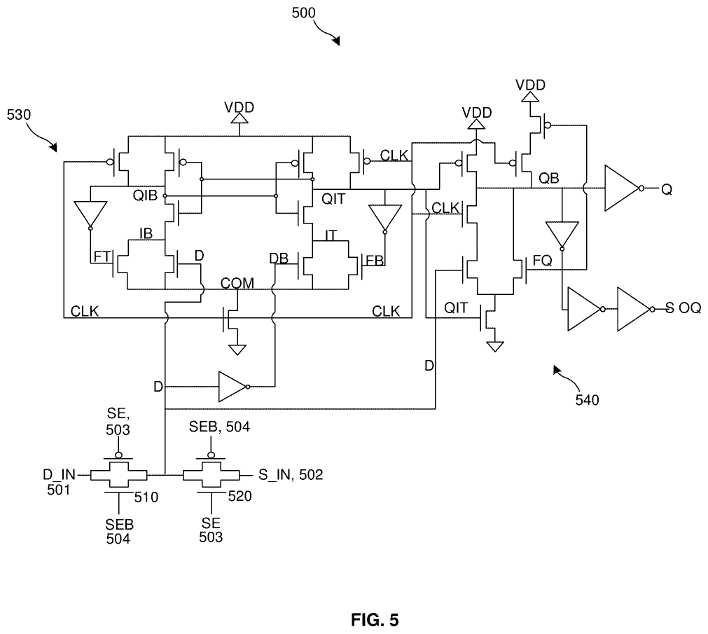

FIG. 5 illustrates a fourth example master slave flip flop circuit 500. In one example, the fourth example master slave flip flop circuit 500 includes a master latch section 530 and a slave latch section 540 which are identical to the master latch section 301 and the slave latch section 302, respectively, of FIG. 3.

In one example, the fourth example master slave flip flop circuit 500 also includes a first scan multiplexer 510 and a second scan multiplexer 520 to select an input for the fourth example master slave flip flop circuit 500 between a data input (D_IN) 501 and a scan input (S_IN) 502. In one example, the data input 501 is used in an operational mode and the scan input 502 is used in a test mode. In one example, the data input 501 is selected if a scan enable (SE) signal 503 is deasserted (i.e., set to LOW) and if a scan enable bar (SEB) signal 504 is asserted (i.e., set to HIGH). In one example, the scan input 502 is selected if a scan enable (SE) signal 503 is asserted (i.e., set to HIGH) and if a scan enable bar (SEB) signal 504 is deasserted (i.e., set to LOW).

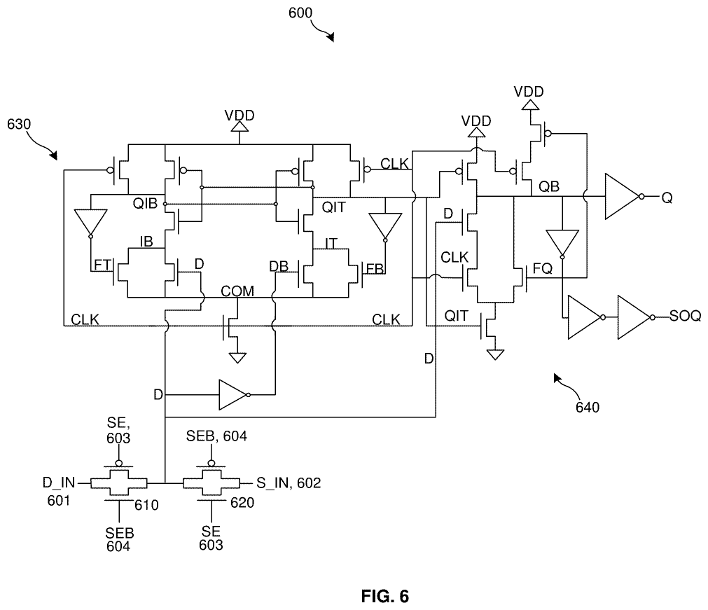

FIG. 6 illustrates a fifth example master slave flip flop circuit 600. In one example, the fifth example master slave flip flop circuit 600 includes a master latch section 630 and a slave latch section 640. In one example, the fifth example master slave flip flop circuit 600 has the master latch section 630 identical to the master latch section 301 of FIG. 3. In one example, the fifth example master slave flip flop circuit 600 has the slave latch section 640 identical to the slave latch section 302 of FIG. 3 except for a swap between the second slave latch transistor 352 and the third slave latch transistor 353. In one example, the transistor swap may result in a less complex layout for the circuit.

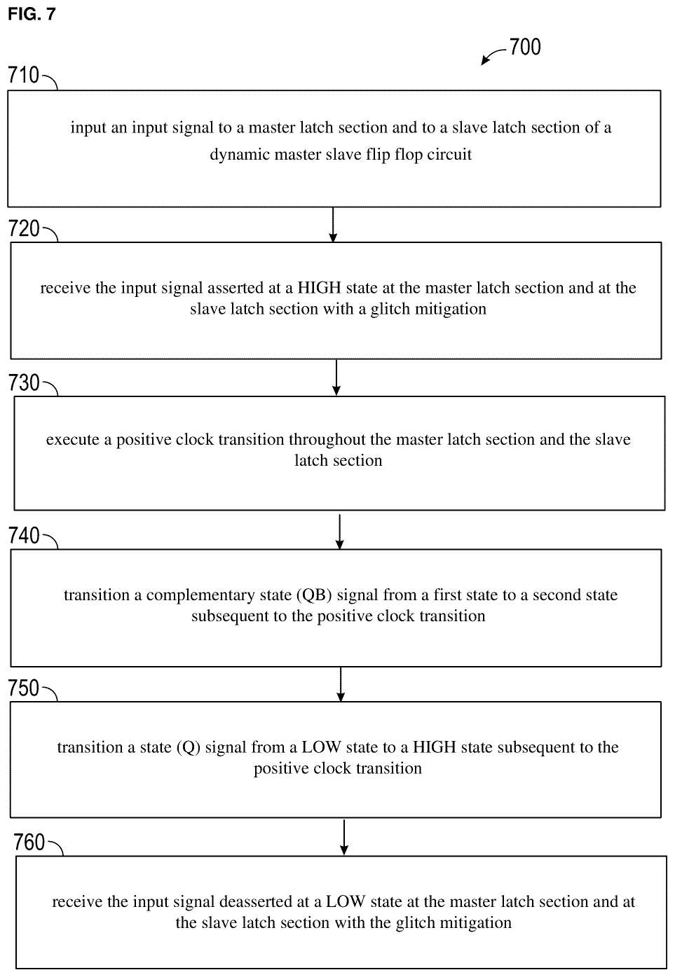

FIG. 7 illustrates an example flow diagram 700 for a dynamic master slave flip flop circuit. In block 710, input an input signal to a master latch section and to a slave latch section of a dynamic master slave flip flop circuit. In one example, an input signal is inputted to a master latch section and to a slave latch section of a dynamic master slave flip flop circuit. In one example, the input signal is a data input signal for an operational mode. In one example, the input signal is a scan input signal for a test mode. In one example, the operational mode or the test mode is selected by a multiplexer coupled to the master latch section. In one example, the input signal is a bilevel digital signal. In one example, the slave latch section prevents an output signal glitch from occurring by pulling down a voltage in an output portion. In one example, the step of block 710 is performed by a transistor, a master latch section, a slave latch section or a slave latch transistor.

In block 720, receive the input signal asserted at a HIGH state at the master latch section and at the slave latch section with a glitch mitigation. In one example, the input signal asserted at a HIGH state is received at the master latch section and at the slave latch section with a glitch mitigation. In one example, the slave latch section includes a glitch-mitigating transistor to provide the glitch mitigation. In one example, the input signal is asserted prior to a setup time margin relative to a positive clock transition. In one example, the step of block 720 is performed by a transistor, a master latch section, a slave latch section or a slave latch transistor.

In block 730, execute a positive clock transition throughout the master latch section and the slave latch section. In one example, a positive clock transition is executed throughout the master latch section and the slave latch section. In one example, the positive clock transition is gated in a keeper circuit. In one example, the positive clock transition is a rising edge of a periodic clock signal. In one example, the periodic clock signal is established using a frequency reference. In one example, a clock circuit is coupled to the master latch section and the slave latch section, wherein the clock circuit is configured to execute a positive clock transition of a clock signal. In one example, the step of block 730 is performed by a clock circuit,

In block 740, transition a complementary state (QB) signal from a first state to a second state subsequent to the positive clock transition. In one example, a complementary state (QB) signal is transitioned from a first state to a second state subsequent to the positive clock transition. In one example, the first state is a HIGH state and the second state is a LOW state. In one example, the complementary state (QB) signal tracks a complement of the input signal with a delay. In one example, the step of block 740 is performed by a transistor, a slave latch section or a slave latch transistor.

In block 750, transition a state (Q) signal from a LOW state to a HIGH state subsequent to the positive clock transition. In one example, a state (Q) signal is transitioned from a LOW state to a HIGH state subsequent to the positive clock transition. In one example, the state (Q) signal tracks the input signal with a second delay. In one example, the step of block 750 is performed by a transistor, a slave latch section, an inverter or a slave latch transistor.

In block 760, receive the input signal deasserted at a LOW state at the master latch section and at the slave latch section with the glitch mitigation. In one example, the input signal deasserted at a LOW state is received at the master latch section and at the slave latch section with the glitch mitigation. In one example, the deassertion transitions the state (Q) signal to a LOW state subsequent to a second positive clock transition. In one example, the step of block 760 is performed by a transistor, a master latch section, a slave latch section or a slave latch transistor.

In one aspect, one or more of the steps for providing a dynamic master slave flip flop circuit in FIG. 7 may be executed by one or more processors which may include hardware, software, firmware, etc. The one or more processors, for example, may be used to execute software or firmware needed to perform the steps in the flow diagram of FIG. 7. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise.

The software may reside on a computer-readable medium. The computer-readable medium may be a non-transitory computer-readable medium. A non-transitory computer-readable medium includes, by way of example, a magnetic storage device (e.g., hard disk, floppy disk, magnetic strip), an optical disk (e.g., a compact disc (CD) or a digital versatile disc (DVD)), a smart card, a flash memory device (e.g., a card, a stick, or a key drive), a random access memory (RAM), a read only memory (ROM), a programmable ROM (PROM), an erasable PROM (EPROM), an electrically erasable PROM (EEPROM), a register, a removable disk, and any other suitable medium for storing software and/or instructions that may be accessed and read by a computer. The computer-readable medium may also include, by way of example, a carrier wave, a transmission line, and any other suitable medium for transmitting software and/or instructions that may be accessed and read by a computer. The computer-readable medium may reside in a processing system, external to the processing system, or distributed across multiple entities including the processing system. The computer-readable medium may be embodied in a computer program product. By way of example, a computer program product may include a computer-readable medium in packaging materials. The computer-readable medium may include software or firmware. Those skilled in the art will recognize how best to implement the described functionality presented throughout this disclosure depending on the particular application and the overall design constraints imposed on the overall system.

Any circuitry included in the processor(s) is merely provided as an example, and other means for carrying out the described functions may be included within various aspects of the present disclosure, including but not limited to the instructions stored in the computer-readable medium, or any other suitable apparatus or means described herein, and utilizing, for example, the processes and/or algorithms described herein in relation to the example flow diagram.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. The terms “circuit” and “circuitry” are used broadly, and intended to include both hardware implementations of electrical devices and conductors that, when connected and configured, enable the performance of the functions described in the present disclosure, without limitation as to the type of electronic circuits, as well as software implementations of information and instructions that, when executed by a processor, enable the performance of the functions described in the present disclosure.

One or more of the components, steps, features and/or functions illustrated in the figures may be rearranged and/or combined into a single component, step, feature or function or embodied in several components, steps, or functions. Additional elements, components, steps, and/or functions may also be added without departing from novel features disclosed herein. The apparatus, devices, and/or components illustrated in the figures may be configured to perform one or more of the methods, features, or steps described herein. The novel algorithms described herein may also be efficiently implemented in software and/or embedded in hardware.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for.”

One skilled in the art would understand that various features of different embodiments may be combined or modified and still be within the spirit and scope of the present disclosure.

What is claimed is:

1. An apparatus comprising:
a master latch section configured to receive an input signal asserted at a HIGH state of the input signal;
a clock circuit coupled to the master latch section, the clock circuit configured to execute a positive clock transition of a clock signal; and
a slave latch section coupled to the master latch section and the clock circuit, the slave latch section configured to transition a state (Q) signal from a LOW state to a HIGH state of the state (Q) signal subsequent to the positive clock transition.

2. The apparatus of claim 1, further comprising a first slave latch transistor configured to implement a glitch mitigation in the slave latch section.

3. The apparatus of claim 2, wherein the first slave latch transistor is housed within the slave latch section.

4. The apparatus of claim 3, wherein the first slave latch transistor is a metal oxide semiconductor (MOS) transistor.

5. The apparatus of claim 4, wherein the metal oxide semiconductor (MOS) transistor is an n-channel MOS (NMOS) transistor.

6. The apparatus of claim 5, further comprising a second slave latch transistor housed within the slave latch section, the second slave latch transistor configured to gate the positive clock transition.

7. An apparatus comprising:
means for receiving an input signal asserted at a HIGH state of the input signal at a master latch section, and at a slave latch section with a glitch mitigation;
means for executing a positive clock transition throughout the master latch section and the slave latch section; and
means for transitioning a state (Q) signal from a LOW state to a HIGH state of the state (Q) signal subsequent to the positive clock transition.

8. The apparatus of claim 7, further comprising means for transitioning a complementary state (QB) signal from a first state to a second state subsequent to the positive clock transition.

9. The apparatus of claim 8, further comprising means for receiving the input signal deasserted at a LOW state.

10. The apparatus of claim 9, further comprising means for inputting the input signal.

11. A method comprising:
receiving an input signal asserted at a HIGH state of the input signal at a master latch section, and at a slave latch section with a glitch mitigation;
executing a positive clock transition throughout the master latch section and the slave latch section; and
transitioning a state (Q) signal from a LOW state to a HIGH state of the state (Q) signal subsequent to the positive clock transition.

12. The method of claim 11, wherein the positive clock transition is gated in a keeper circuit.

13. The method of claim 11, wherein the positive clock transition is a rising edge of a periodic clock signal.

14. The method of claim 13, wherein the periodic clock signal is established using a frequency reference.

15. The method of claim 11, further comprising transitioning a complementary state (QB) signal from a first state to a second state subsequent to the positive clock transition.

16. The method of claim 15, wherein the complementary state (QB) signal tracks a complement of the input signal with a first delay.

17. The method of claim 16, wherein the state (Q) signal tracks the input signal with a second delay.

18. The method of claim 15, further comprising receiving the input signal deasserted at a LOW state at the master latch section, and at the slave latch section with the glitch mitigation.

19. The method of claim 18, further comprising inputting the input signal to the master latch section and to the slave latch section.

20. The method of claim 18, wherein the input signal is received prior to a setup time margin relative to the positive clock transition.
